(19) United States
(12) Patent Application Publication
(10) Pub. No.: US 2009/0064790 A1
(43) Pub. Date: Mar. 12, 2009

(54) Microreactor Glass Diaphragm Sensors

(75) Inventors: Jerome Vivien Davidovits, Thomery (FR); James Scott Sutherland, Corning, NY (US)

Correspondence Address: CORNING INCORPORATED, SP-TI-3-1, CORNING, NY, 14831, US

(73) Assignee: CORNING INCORPORATED, Corning, NY (US)

(21) Appl. No.: 12/087,394

(22) PCT Filed: Dec. 22, 2006
(86) PCT No.: PCT/US2006/049251

§ 371 Date: Jun. 30, 2008

Related U.S. Application Data
(60) Provisional application No. 60/755,601, filed on Dec. 31, 2005.

(51) Int. Cl. G01L 9/12; G01L 9/04; H01L 21/00

(52) U.S. Cl. 73/718; 73/720; 438/53; 257/E21.001

(57) ABSTRACT

Microfluidic devices having wall structures comprised of sintered glass frit and further including a glass, glass-ceramic or ceramic membrane structure sealed by a sintered seal to said wall structures, such that a fluid passage or chamber is defined at least in part by the wall structures and said membrane structure. This allows for changes in pressure within the fluid passage or chamber to cause deflections of the membrane structure, providing for direct measurement of pressure within the device. The microfluidic device may have both floors and walls of sintered frit, or may have only walls of sintered frit, with planar floor-like substrate structures, thicker than the membrane structure defining the vertical boundaries of the internal passages. The device may include multiple fluid passages or chambers each defined at least in part by a membrane structure. Multiple membrane structures may be used in a single device, and one single membrane structure may be used for multiple passages or chamber.

This application claims priority to U.S. provisional application No. 60/755,601 filed Dec. 31, 2005.

### BACKGROUND OF THE INVENTION

1. Field of the Invention

The present invention relates generally to pressure sensing devices integrated into glass, glass-ceramic, or ceramic microreactor fluidic structures for use in chemical processing, and particularly to glass microreactor pressure sensors that are fabricated using glass, glass-ceramic, or ceramic sheets and glass frit (i.e., glass powder).

2. Technical Background

Microreactor-type chemical processing units have been proposed where fluids (liquids or gases) are guided in etched, molded, drilled or otherwise formed fluid channels in or on planar substrates. Fluid channels are patterned with elementary fluidic structures (e.g., mixers and residence time segments) to form circuits that provide more complex chemical processing functions. Planar substrates can be stacked to extend functionality in a single reaction unit, providing a modular chemical processing system that can target multiple applications.

Because of its transparency, chemical and physical durability, biological and chemical inertness, tolerance of extreme temperatures and other properties, glass is an attractive material for use in such microreactor devices. In using microreactors and similar microfluidic devices, it is desirable to be able to detect the internal pressure at key points within the device or at key points within the process performed in the device. Chemical processing systems, for example, often require active monitoring of fluid pressures for process control and safety monitoring functions. A sudden change in operating pressure could indicate an abnormal processing condition or a leak in the reactor device.

However, the very properties of chemical and physical durability that make glass materials desirable also make them difficult to form into complex structures. A simple way to form microreactor and other microfluidic structures in glass, with provision for integrated in situ pressure sensing, is thus desirable.

### SUMMARY OF THE INVENTION

The present invention includes among its embodiments integrated pressure sensors in glass-frit based microfluidic devices, as well as methods for producing integrated pressure sensors in a glass-frit based microfluidic devices. According to one embodiment, the method includes providing a flexible glass, glass-ceramic or ceramic membrane, and forming out of glass frit wall structures that define, at least in part, at least one microfluidic chamber or passage in which pressure is to be sensed, and sintering the wall structures while the wall structures are in contact with the membrane such that resulting sintered walls form a seal with the membrane such that the membrane forms a boundary of the at least one chamber or passage.

The step of forming wall structures may further include forming wall structures upon a substrate other than said membrane. This other substrate may be, but is not required to be, a glass substrate. This other substrate may also be a ceramic or a glass-ceramic substrate, for example. The step of forming wall structures may alternatively or in addition include forming wall structures directly upon the membrane.

As another alternative, glass frit based floor structures may also be formed, and may form a boundary of the chamber or passage opposite the membrane.

As yet another variation of this embodiment of the inventive method, the step of forming microfluidic chamber or passage wall structures may include defining multiple chambers or passages in which pressure is to be sensed. If desired, the same membrane may be used to form a boundary of the multiple chambers or passages.

The wall structures may be formed as both thin and thick wall structures, and the membrane may be sintered and sealed only to the thin wall structures, if desired. This is one way in which the membrane may be located internally in the device, as is explained in the detailed description below.

Another aspect of the present invention relates to a microfluidic device having wall structures comprised of sintered glass frit and a glass, glass-ceramic or ceramic membrane structure sealed by a sintered seal to said wall structures, such that a fluid passage or chamber is defined at least in part by the wall structures and said membrane structure. This allows for changes in pressure within the fluid passage or chamber to cause deflections of the membrane structure, providing for direct measurement of pressure within the device. The microfluidic device may have both floors and walls of sintered frit, or may have only walls of sintered frit, with planar floor-like substrate structures, thicker than the membrane structure defining the vertical boundaries of the internal passages. The device may include multiple fluid passages or chambers each defined at least in part by a membrane structure. Multiple membrane structures may be used in a single device, and one single membrane structure may be used for multiple passages or chambers.

Deflection of the deflectable areas of the membrane or membranes in a given device may be accomplished by capacitive or optical detection, or by a strain gauge, or other suitable means.

Additional features and advantages of various embodiments of the invention will be set forth in the detailed description which follows, and in part will be readily apparent to those skilled in the art from that description or recognized by practicing the invention as described herein, including the detailed description which follows, the claims, as well as the appended drawings.

It is to be understood that both the foregoing general description and the following detailed description present embodiments of the invention, and are intended to provide an overview or framework for understanding the nature and character of the invention as it is claimed. The accompanying drawings are included to provide a further understanding of the invention, and are incorporated into and constitute a part of this specification. The drawings illustrate various embodiments of the invention and together with the description serve to explain the principles and operations of the invention.

### BRIEF DESCRIPTION OF THE DRAWINGS

FIG. 1 is a flow diagram of one embodiment of a process of the present invention;

FIG. 2 is a cross-sectional view of a microfluidic device according to an embodiment of the present invention;

FIG. 3 is a cross-sectional view of a microfluidic device according to another embodiment of the present invention;

FIG. 4 is a partial perspective view of another embodiment of a device, partially assembled, according to the present invention;

FIG. 5 is the a cross-sectional view of a device according to yet another embodiment of the present invention;

FIG. 6 is a graph of deformation, as a function of pressure, of membranes of a type useful in the context of the present invention.

### DETAILED DESCRIPTION OF THE PREFERRED EMBODIMENTS

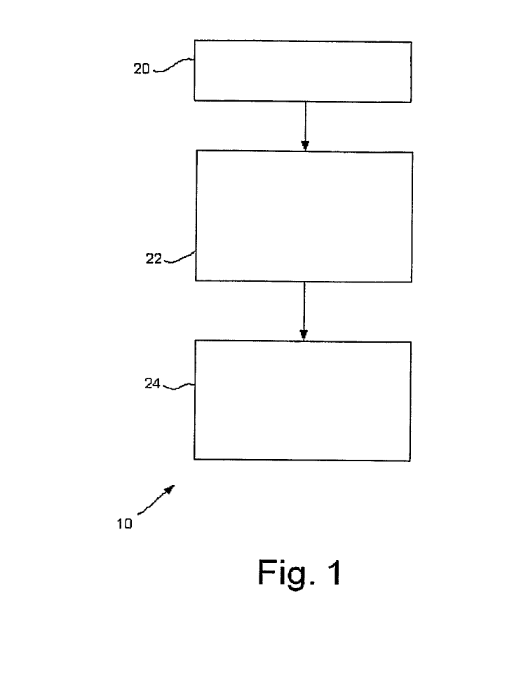

Reference will now be made in detail to the present preferred embodiment(s) of the invention, examples of which are illustrated in the accompanying drawings. Whenever possible, the same reference numerals will be used throughout the drawings to refer to the same or like parts. One embodiment of a method of the present invention is shown in FIG. 1, and is designated by the reference numeral 10. The method 10 illustrated in FIG. 1 constitutes the basic steps of an embodiment of a method for producing an integrated pressure sensor in a glass-frit based microfluidic device.

The method includes step 20, providing a flexible glass, glass-ceramic or ceramic membrane. Glass may be preferred for its transparency, but transparency is not a requirement. Strength and a degree of flexibility are more important. The method also includes step 22, forming microfluidic wall structures defining at least one chamber or passage in which pressure is to be sensed, the wall structures comprising glass frit. The wall structures comprising a glass frit may be formed by press-molding, injection molding, thermo-forming or other techniques or combinations of these forming methods, typically employing an organic binder to allow the frit to be formed. Forming methods employing frit allow the formation of relatively complex structures as an up-building process rather than as a subtractive process which can be difficult and expensive in glass materials. The wall structures may be molded or otherwise formed integrally with their own floor structure or on a substrate such as a glass, glass-ceramic or ceramic substrate. Alternatively, the wall structures may be molded or otherwise formed directly onto the membrane. However formed, the frit wall structures are placed in contact (if not already in contact) with the membrane and sintered in step 24. Step 24 is sintering the wall structures while the wall structures are in contact with the membrane such that resulting sintered walls form a seal with the membrane. This results in the membrane forming a deformable boundary of a fluidic chamber or passage within the microfluidic device, and displacement of the membrane is then used to measure pressure or pressure variation within the microfluidic device.

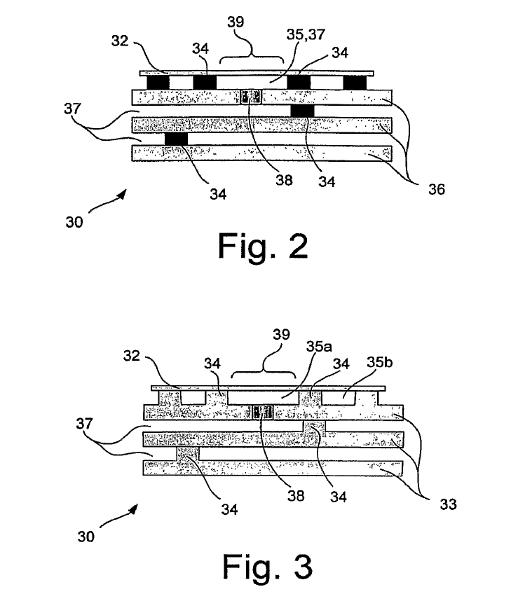

FIG. 2 is a cross-sectional view of an embodiment of microfluidic device 30 according to the present invention. In this embodiment, frit walls 34 have been formed on glass substrates 36. Fluid passages 37 are defined by the walls 34 and the substrates 36. A glass membrane 32 has been placed in contact with the frit walls 34 on the top of the substrate 36 uppermost in the figure. A fluid chamber 35 or fluid passage 37 is defined by the membrane 32, particularly by the deformable portion 39 thereof, together with the associated frit walls 34 and substrate 36. A through-hole 38 through the associated substrate 36 provides access to the chamber 35 or fluid passage 37. Although this embodiment and other embodiments of the invention will work with a fluid chamber 35 (i.e., with a dead-end chamber 35 having no flow through it during normal microfluidic device operation), it is generally preferred to use a fluid passage 37 (with flow, for example, in the direction into the plane of the figure) rather than a dead-end chamber, as a means of reducing the chances of fouling. The state of the device as shown in FIG. 1 may be understood as just before sintering. The sintering step then serves to seal or fuse each of the frit walls with the adjacent substrate or membrane material. Thus the pressure sensor is formed by sealing to the frit walls 34 simultaneously with the rest of the fluid passages 37 of the microfluidic device.

FIG. 3 shows an embodiment similar but alternative to that of FIG. 2. In the embodiment of FIG. 3, no substrates 36 are present. Instead, the wall structures 34 have been formed of frit material integrally with floor structures 33 formed of the same frit material. Thus the desired structures can be formed without the potential limitations imposed by the use of substrates, such as the potential difficulty of providing through-holes. Though-hole 38 of FIG. 3 need only be molded into the frit material forming the floor structures 33. The embodiment of FIG. 3 also differs from that of FIG. 2 in that first and second chambers 35a and 35b are both sealed by the membrane 32. Thus multiple sensors may be provided for in a single device, and even with a single membrane 32. Of course multiple membranes may be used if desired.

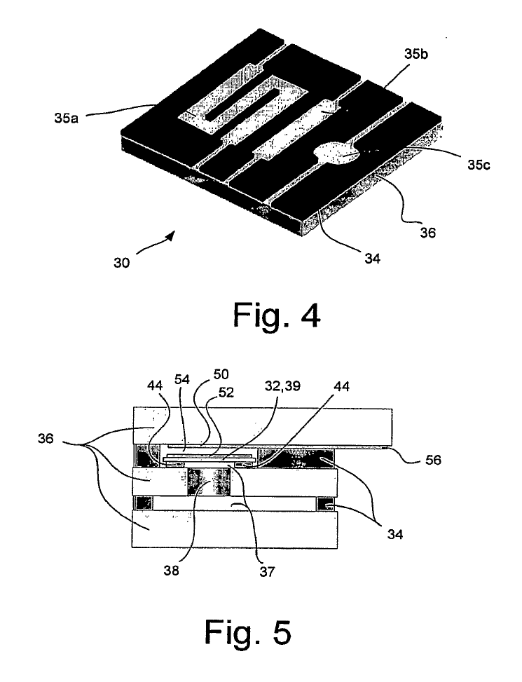

FIG. 4 shows a perspective view of a portion of another device according to the present invention. FIG. 4 shows a substrate 36 with a layer of frit wall material disposed on it. The frit walls define three differently shaped chambers or passages 35a, 35b, and 35c. A membrane has not yet been brought into contact with the frit walls of FIG. 4, so that shapes and profiles of the various alternative chambers 35 may be readily seen.

FIG. 5 is a cross-sectional view of a device according to yet another embodiment of the present invention. In the device of FIG. 5, substrates 36 protect the outermost portions of the device (in the up and down direction in the figure). In addition to the normal-height frit walls 34, the device includes thin or short frit walls 44, upon which a membrane 32 is positioned between the outermost substrates. Membrane 32 is provided with fluid (and fluid pressure) through through-hole 38. The basic structure for capacitive pressure sensing is also provided in the embodiment of FIG. 5. One electrode in the form of a layer of conductive material 52 is disposed on the membrane 32. A second electrode in the form of a conductive layer 50 is disposed nearby on the underside of the uppermost of the substrates 30 in the figure, and extends rightward to a contact point 56. From contact point 56 the capacitance of the capacitor formed by layers 50 and 52, and the intervening air gap 54, may be measured, thus allowing deformation of the membrane 32 to be measured, and the associated pressure to be measured.

Alternatives to the capacitive detection of deflection of membrane 32 include optical detection such as with interferometric detection using a mirrored surface or other optically detectable surface disposed on the membrane in place of conductive layer 52. As another alternative, a strain gauge may be disposed on the membrane in place of conductive layer 52.

### Experimental

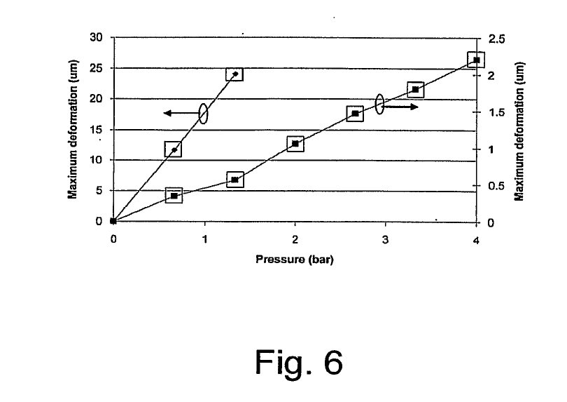

Experiments on glass diaphragm deformation under applied pressure were performed. Thin glass diaphragms with thicknesses of 0.186 and 0.7 mm were clamped in a pressure testing fixture and restrained to create an 8 mm diameter circular diaphragm. Pressures of up to 4 bars were applied to the diaphragms, with diaphragm deformation measured during pressurization via surface interferometry. Results are plotted in the graph of FIG. 6. Error boxes around data points indicate measurement uncertainty due to pressure gauge reading and surface interferometry diaphragm edge determination. The results show relatively good linearity over a relatively wide pressure range.

Embodiments described above enable integration of pressure sensing in an all-glass or all glass, ceramic, and/or glass-ceramic or related type microreactor while adding no additional, or at least a minimum of additional process steps, and while preserving, if desired, an all-glass environment within the fluidic channels or chambers. Such integration may be used to avoid the need for external sensors with the typical resulting proliferation of fluidic connections and dead volumes, and may be used to provide a way to directly detect pressure and/or other important properties of the internal microfluidic environment. The pressure sensors of the present invention may be applied, in combination with each other or with other sensors, to detect mass flow rates, for example.

It will be apparent to those skilled in the art that various modifications and variations can be made to the present invention without departing from the spirit and scope of the invention. Thus it is intended that the present invention cover the modifications and variations of this invention provided they come within the scope of the appended claims and their equivalents.

What is claimed is:

1. A microfluidic device comprising:
wall structures comprised of sintered glass frit;
a glass, glass-ceramic or ceramic membrane structure sealed by a sintered seal to said wall structures;
a fluid passage or chamber defined at least in part by said wall structures and said membrane structure, said membrane structure being deflectable by changes in pressure within the fluid passage or chamber.

2. The device according to claim 1 further comprising at least one planar substrate structure sealed to said wall structures by a sintered seal, the planar substrate structure being thicker than the membrane structure, the passage or chamber being defined by the planar substrate structure and the wall structures and the membrane structure.

3. The device according to claim 1, further comprising one or more floor structures formed of sintered glass frit and wherein the passage or chamber is defined by the planar substrate structure and the wall structures and at least one of the one or more floor structures.

4. The device according to claim 1 further comprising multiple fluid passages or chambers each defined at least in part by said wall structures and by a respective area of said membrane structure, whereby changes in pressure within each respective fluid passage or chamber cause deflections of respective areas of the membrane structure.

5. The device according to claim 1 further comprising an electrode of a capacitor structure disposed on the surface of the membrane whereby deflections of the membrane may be detected as changes in the capacitance of the capacitor structure.

6. The according to claim 1 further comprising an optical element disposed on the surface of the membrane whereby deflections of the membrane may be detected optically due to motion of the optical element.

7. The device according to claim 6 wherein the optical element comprises a grating.

8. The device according to claim 6 wherein the optical element comprises a reflector.

9. The device according to any of claim 1 further comprising a strain gauge structure disposed on the surface of the membrane whereby deflections of the membrane may be detected via the strain gauge.

10. A method for producing an integrated pressure sensor in a sintered-glass-frit-containing microfluidic device, the method comprising:
providing a flexible glass, glass-ceramic or ceramic membrane;
forming microfluidic chamber or passage wall structures defining at least one chamber or passage in which pressure is to be sensed, the wall structures comprising a glass frit;
sintering the wall structures while the wall structures are in contact with the membrane such that resulting sintered walls form a seal with the membrane, and the membrane forms a boundary of the at least one chamber or passage.
